(19) United States
(12) Patent Application Publication
(10) Pub. No.: US 2026/0165129 A1
(43) Pub. Date: Jun. 11, 2026

(54) IMMERSION COOLING OF EMBEDDED ELECTRONIC COMPONENTS

(71) Applicant: SEMICONDUCTOR COMPONENTS INDUSTRIES, LLC, Scottsdale, AZ (US)

(72) Inventor: Seungwon IM, Bucheon (KR)

(73) Assignee: SEMICONDUCTOR COMPONENTS INDUSTRIES, LLC, Scottsdale, AZ (US)

(21) Appl. No.: 18/976,184

(22) Filed: Dec. 10, 2024

(51) Int. Cl. H01L 23/44; H01L 21/48; H01L 23/40; H01L 23/538; H01L 25/07

(52) U.S. Cl. CPC H10W 40/30; H10W 40/037; H10W 40/641; H10W 70/611; H10W 90/00; H10W 90/401

(57) ABSTRACT

Electronic assemblies that perform immersion cooling of embedded electronic components are described herein, as well as methods for constructing the same. An example electronic assembly includes a first carrier and a second carrier joined together to form a composite carrier. A set of components forming an electronic circuit are embedded within this composite carrier between the first carrier and the second carrier. A plurality of leads integrated with the composite carrier are configured to provide external access to a plurality of circuit nodes of the electronic circuit. An immersive cooling assembly at least partially enclosing the composite carrier is configured to guide a cooling fluid over the composite carrier.

### BACKGROUND

Packaging plays a critical role in ensuring the proper function, reliability, and ease of use of electronic components. Proper packaging of electronic components may serve various roles. For example, one function of a package may be to protect a delicate semiconductor die inside the package from physical damage, contamination, electrostatic discharge (ESD), etc., since these threats could render the component inoperable if the die is not properly protected. Similarly, the package may also provide a barrier against moisture and exposure to other environmental elements that could lead to degradation and malfunction of the component. Another role of the package may be to facilitate electrical connections between the internal circuitry of the component and external circuitry (e.g., of a circuit board to which the electronic component is coupled, etc.). For example, metal pins, leads, bumps, and other such features may allow for the electrical component to be soldered onto or otherwise connected to a printed circuit board.

Heat dissipation may also be provided by packaging that is configured to facilitate heat transfer away from operational elements of the component (e.g., the semiconductor die inside the device package). In some cases, electronic component packaging may include or be configured to interface with additional cooling mechanisms, such as by connecting to an external heatsink (e.g., a passive heat sink, a fluid-based active cooling device, etc.).

### SUMMARY

Power electronics are configured to process relatively large voltages and currents for automotive, industrial, and other high-power applications and use cases. As these devices and systems generate, consume, and/or otherwise process and use electrical power, a significant amount of heat may be generated. In order for the power circuitry to function properly, it may be desirable to facilitate dissipation of this heat or even active removal or transfer of the heat away from the electronic components generating it. Conventional approaches to such heat removal have included passive heatsinks and active, fluid-based cooling systems (also referred to as active coolers) on which electronic components can be physically attached (e.g., installed on a surface of the heat sink or cooler).

To further advance cooling capabilities for at least certain systems and scenarios, immersion cooling implementations described herein are configured to help remove heat from certain electronic assemblies even more effectively and efficiently than these conventional approaches. For example, electronic assemblies described herein may feature electronic components that form an electronic circuit embedded within a composite carrier (e.g., implemented within or between two carrier boards to completely encompass or encapsulate the electronic circuit and the components and connections thereof). Electronic assemblies described herein may include, along with a composite carrier embedding an electronic circuit, a cooling assembly configured to perform immersion cooling of the electronic circuit. For example, by partially surrounding the composite carrier (e.g., composed of two printed circuit boards joined together with circuit components in between) and passing cooling fluid over at least two sides of the carrier, the various electronic components of the electronic circuit may be actively cooled in a highly effective and efficient manner.

As one example implementation, an electronic assembly (e.g., an automotive power inverter assembly for an electric or hybrid vehicle, etc.) may include: 1) a first carrier and a second carrier (e.g., each implemented as printed circuit boards or other suitable boards or circuit carrying structures), the first carrier being joined to the second carrier to form a composite carrier; 2) a set of components forming an electronic circuit, the set of components being embedded within the composite carrier between the first carrier and the second carrier; 3) a plurality of leads integrated with the composite carrier and configured to provide external access to a plurality of circuit nodes of the electronic circuit; and 4) an immersive cooling assembly at least partially enclosing the composite carrier and configured to guide a cooling fluid over the composite carrier.

As another example implementation, a method (e.g., a manufacturing process for fabricating an assembly or system such as described above) may include: 1) integrating a plurality of leads with a first carrier (e.g., a first printed circuit board or other suitable board or circuit carrying structure); 2) coupling a set of components to the first carrier, the set of components forming an electronic circuit that includes a plurality of circuit nodes externally accessible via the plurality of leads; 3) subsequent to coupling the set of components to the first carrier, joining the first carrier to a second carrier (e.g., a second printed circuit board or other suitable board or circuit carrying structure) to form a composite carrier; and 4) assembling an immersive cooling assembly to at least partially enclose the composite carrier, the immersive cooling assembly being configured to guide a cooling fluid over the composite carrier.

As another example implementation, power inverter assembly may include: a first carrier (e.g., a first printed circuit board) and a second carrier (e.g., a second printed circuit board), the first carrier being joined to the second carrier to form a composite carrier; 2) a set of components forming a power inverter circuit, the set of components including a plurality of unpackaged semiconductor dies each implementing singular power transistors and the set of components being embedded within the composite carrier between the first carrier and the second carrier; 3) a plurality of leads integrated with the composite carrier and configured to provide external access to a plurality of circuit nodes of the power inverter circuit; and 4) an immersive cooling assembly configured for use in an automotive application, the immersive cooling assembly at least partially enclosing the composite carrier and configured to guide a cooling fluid over the composite carrier.

Each of the preceding example implementations will be understood to be illustrative of the types of implementations that are consistent with the following description. It will be understood that these examples are not intended to be limiting and that any of the aspects mentioned above or described herein may be used with any of the implementations in accordance with principles described herein. The details of these and other implementations are set forth in the accompanying drawings and the description below. Other features will also be apparent from the following description, drawings, and claims.

### BRIEF DESCRIPTION OF THE DRAWINGS

FIG. 1 shows certain aspects of an illustrative implementation of an electronic assembly configured to perform immersion cooling of embedded electronic components in accordance with principles described herein.

FIGS. 2A-2E show different views of an illustrative implementation of an electronic assembly configured to perform immersion cooling of embedded electronic components in accordance with principles described herein.

FIGS. 3A-3B contrast certain aspects of a conventional cooling system and an electronic assembly configured to perform immersion cooling of embedded electronic components in accordance with principles described herein.

FIG. 4 shows an illustrative method for constructing an electronic assembly configured to perform immersion cooling of embedded electronic components in accordance with principles described herein.

FIG. 5 shows illustrative aspects related to preparing a carrier and a plurality of leads for an electronic assembly in accordance with principles described herein.

FIG. 6 shows illustrative aspects related to coupling components to the carrier of FIG. 5 in accordance with principles described herein.

FIG. 7 shows illustrative aspects related to joining two carriers to form a composite carrier with an embedded electronic circuit in accordance with principles described herein.

FIG. 8 shows illustrative aspects of a first type of electronic assembly that can be fabricated using the method of FIG. 4 in accordance with principles described herein.

FIG. 9 shows illustrative aspects of a second type of electronic assembly that can be fabricated using the method of FIG. 4 in accordance with principles described herein.

### DETAILED DESCRIPTION

Electronic devices and components are configured to operate properly within certain temperature parameters. As a result, passive and/or active temperature control mechanisms may be used to help maintain the temperature within desired parameters as electronics operate. More particularly, principles described herein relate to immersion cooling of embedded electronic components (e.g., electronic components forming an electronic circuit while being embedded between two carriers forming a composite carrier). For instance, the carriers may each be implemented by printed circuit boards or other suitable types boards or circuit carrying structures or substrates (e.g., direct-bonded metal substrates, etc.). Various implementations of these principles include electronic assemblies, apparatuses, devices, systems, and so forth, along with methods, processes, and techniques for constructing the same.

Certain types of electronics may be especially challenging to maintain within desired temperature ranges. As one example, electronic devices that consume or produce a large amount of power (e.g., power inverter modules, high-power processors, electronics using power field-effect transistors (FETs) and/or other types of power transistors, etc.) may tend to heat up significantly during operation and require significant cooling. For instance, applications and use cases in the automotive space (e.g., electric vehicles (EVs), hybrid vehicles, etc.) and/or in other industrial contexts with large-scale machinery may employ electronics harnessing large amounts of power that may cause the circuitry to produce significant amounts of heat.

As another example, electronic devices operating in certain environments (e.g., warm outdoor environments, enclosed environments with limited natural airflow, etc.) may also tend to be challenging to properly cool. While passive cooling involving various types of heatsinks and natural airflow may be suitable for cooling certain electronics, active cooling involving forced passage of gaseous or liquid coolants may be used in more challenging scenarios.

Passive heat sinks and active coolers generally operate by connecting to electronic components that tend to produce large amounts of heat during operation. For example, one or more such components may be installed on (i.e., physically coupled to) a surface of a heatsink or active cooler so that heat from the components will be absorbed into the heatsink or active cooler (e.g., by heat conduction by virtue of the physical coupling) and then dissipated into the atmosphere or elsewhere. A passive heatsink may operate by having many heat-conductive fins, pins, or other elements that give the passive heatsink a large surface area with which to transfer heat into the ambient air. Similarly, an active color may operate by pumping fluid through a manifold that is physically attached to the heat source (e.g., the electronic component) such that the fluid can heat up when in contact with the heat source (thereby absorbing some of its heat) and can then carry the heat away and dissipate it into the environment or elsewhere as the fluid cools off. In some cases, a passive heatsink and an active cooler may be used in combination with one another to attempt to cool electronic components even more effectively.

At least one technical problem that conventional cooling approaches face, however, is that there is a limit to how efficiently heat can transfer from one surface of an electronic component to a plate of a cooling system (e.g., a surface of a passive heatsink or active cooler to which the electronic component is attached). If the bottom of a flat component is installed on a cooling device, for example, a significant amount of heat may be drawn out of the bottom of the component as it heats up and some heat may radiate out of the top, but depending on how much heat is being produced, there may be a bottleneck in the heat transfer that disallows the amount of heat dissipation that may be desired. Additionally, even if a larger cooling system is used in an attempt to draw out and dissipate heat at a higher rate to keep up with the amount of heat being produced, another technical challenge may arise relating to the size of the cooling system, since it may be desirable for these electronics to be disposed in relatively tight quarters (e.g., under a hood of a vehicle with an engine and many other components where physical space is at a premium).

At least one technical solution described herein to address these technical problems relates to immersion cooling of embedded electronic components. Rather than packaging electronic components in traditional ways (e.g., using expensive substrates and wire bonding to form circuits and molding compounds to seal in and protect them, etc.) certain circuits may be formed by unpackaged electronic components being disposed directly on one carrier (e.g., a printed circuit board that helps provide desired connections between the components) and then having a second carrier joined over the top of the components so as to fully embed and protect the circuitry between the two carriers. This combination of two carriers (so that electronic components forming an electronic circuit can be embedded within) is referred to herein as a composite carrier. As used herein, various types of circuit carriers (e.g., a first carrier, a second carrier, a composite carrier, etc.) may be referred to as carriers or carrier boards. As will be described, it will be understood that such carriers may be implemented by carrier boards (e.g., printed circuit boards, other suitable boards without printed circuit elements, etc.) or by other suitable circuit carrying structures or substrates (e.g., direct bonded metal substrates, etc.).

There may be several technical effects and advantages to packaging electronic components in this way (i.e., embedding the components within a composite carrier board). At least one technical effect, for example, is that the delicate electronic components embedded within the composite carrier board may be well protected from the environment, including from cooling fluids that, if coming into direct contact with the components, could erode the components or otherwise cause the circuit to malfunction or experience issues. With this protection in place, however, immersion cooling techniques described herein involve installing immersive cooling assemblies around composite carrier boards (i.e., so that the immersive cooling assembly at least partially encloses the composite carrier board (with its embedded circuitry, as described above). By enclosing the circuitry in this way, immersive cooling assemblies described herein may guide cooling fluid over composite carrier boards to more efficiently and effectively absorb heat produced by circuitry embedded therein. In some examples, this enclosing of the composite carrier board allows for the cooling fluid to not only be guided over one side of the composite carrier board but to also be simultaneously guided over the opposite side of the composite carrier board as well.

The technical effects and advantages from allowing cooling fluid to make direct contact with both sides of a composite carrier board enclosing an electronic circuit may be significant. As one example, heat may be transferred more efficiently to cooling fluid that is brought into direct contact with a composite carrier board as compared to heat transfer from an electronic component to a cooling system onto whose surface the component is installed (e.g., by way of a solder pad that has its own imperfections such as will be described and illustrated in more detail below) in the conventional scenario. This means that the circuit may be cooled more efficiently, thereby enabling, potentially, a more compact, space-saving cooling package to be used (e.g., an immersive cooling assembly configured to produce the same cooling as a conventional active cooler but that takes up less space).

Other technical effects and benefits of immersion cooling principles described herein include that no solder need be used to couple the electronic circuits to the immersive cooling system (since the system encloses the composite carrier board and guides cooling fluid directly over the board (e.g., including both sides of the board in some examples). Moreover, immersive cooling assemblies may be advantageous in that they allow for compact packaging of the cooling solution, as well as reduced costs as certain manufacturing processes may be omitted and/or otherwise simplified (e.g., eliminating potentially expensive substrates; omitting assembly steps such as for die attach, wire bonding, molding, trimming, and finalization of the package; and so forth). Power savings arising from increases in cooling efficiency and effectiveness may also be provided by immersion cooling principles described herein, as will be made apparent in the following description.

While principles described herein may be advantageous in a variety of contexts, applications, and use cases, a concrete example of a power inverter assembly (e.g., such as may be configured for use in an automotive context such as within an electric vehicle) will be used as a running example throughout the following description. As will be described, power inverters may be useful in various contexts such as in converting direct current (DC) power from a battery of an electric vehicle into alternating current (AC) power that can be used to perform the mechanical work involved in propelling the vehicle. As such, and as will be described in more detail below, automotive power inverter devices described herein may apply immersion cooling principles to efficiently transfer heat away from embedded electronic components and provide benefits described herein.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Immersion cooling of embedded electronic components in accordance with principles described herein may result in any or all of the technical effects mentioned above, as well as various additional technical effects and benefits that will be described and/or made apparent below.

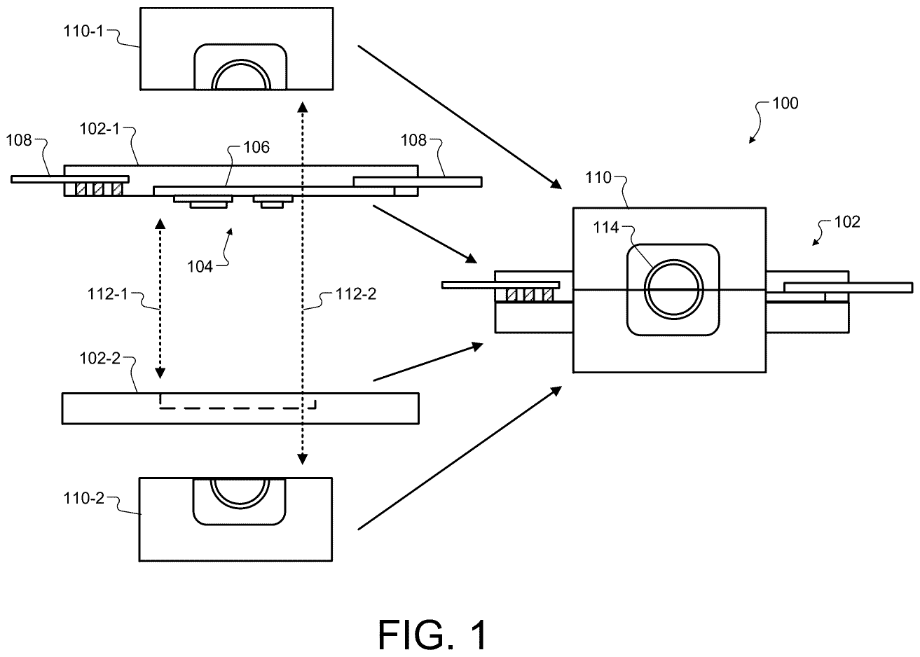

FIG. 1 shows certain aspects of an illustrative implementation of an electronic assembly 100 configured to perform immersion cooling of embedded electronic components in accordance with principles described herein. More particularly, the electronic assembly 100 in FIG. 1 is shown, in an exploded view on the left and an assembled side view on the right, to include a variety of elements that collectively perform both 1) the function of a particular electronic circuit (e.g., a power inverter or other suitable circuit), and 2) the function of cooling that electronic circuit during its operation (i.e., dissipating the heat that the circuit produces). As shown, these elements of electronic assembly 100 include: a first carrier board 102-1 and a second carrier board 102-2 that are joined to form a composite carrier board 102, a set of components 104 forming an electronic circuit and including an electrical connection 106 that is provided by (e.g., integrated with) the first carrier board 102-1, a plurality of leads 108, and an immersive cooling assembly 110 (including at least a first portion 110-1 and a second portion 110-2 that combine to form the immersive cooling assembly 110).

As shown by assembly steps 112-1 and 112-2 drawn in relation to the exploded view, the various elements of electronic assembly 100 may be assembled in multiple operations (such operations will be described in more detail below with reference to methods and processes for constructing an electronic assembly such as electronic assembly 100). More particularly, step 112-1 shows how carrier boards 102-1 and 102-2 may be joined together to form the composite carrier board 102 within which the set of components 104 forming an electronic circuit are embedded. Step 112-2 then shows how the portions 110-1 and 110-2 of immersive cooling assembly 110 may be assembled around the composite carrier board 102 so as to at least partially enclose the carrier board 102 and provide ports, (e.g., including at least one port 114 and another port not shown in the view of FIG. 1) for cooling fluid to be introduced to the composite carrier board 102 for the purpose of cooling the electronic circuit. Each of these elements will now be described in more detail.

Composite carrier board 102 is shown to be a composite of the first carrier board 102-1 and the second carrier board 102-2 when these are joined together at step 112-1. Each of carrier boards 102-1 and 102-2 may be implemented in any suitable way so as to provide a platform on which an electronic circuit can be built (e.g., by carrying and providing structural support for components of the circuit, by providing electrical connections between some or all of the components, etc.). As one example, the first carrier board may be a first printed circuit board (PCB), and the second carrier board may be a second PCB. In this case, the electronic circuit may include various components coupled to the PCB (e.g., to the first PCB in particular), as well as one or more electrical connections such as electrical connection 106 provided by the PCBs (e.g., by the first PCB, as shown). For instance, these electrical connections, including electrical connection 106, may each include pads (e.g., a first pad and a second pad) and traces connecting them (e.g., a trace connecting the first pad and the second pad within the first PCB).

By constructing a circuit on the first PCB and then enclosing the circuit between the first PCB (i.e., first carrier board 102-1) and the second PCB (i.e., second carrier board 102-2), the set of components 104 making up the circuit may be protected from moisture (e.g., cooling fluid to be guided over the surface of the composite carrier board 102) and other environmental elements that could harm or interfere with the components if they were not enclosed and protected by the PCBs. For example, rather than fluid flowing through an isolated channel or chamber within the immersive cooling assembly 110 (e.g., a compartment provided by the cooling assembly and configured to keep the fluid from directly contacting the PCBs), the fluid can be guided to make direct contact with composite carrier board 102 to facilitate efficient heat transfer from the circuit, through the carrier boards (e.g., the PCBs) and into cooling fluid as it is pumped through the cooling assembly.

In other examples, other types of carrier boards could be used instead of or in connection with the PCBs described above. For instance, some or all of the components 104 could be disposed on a substrate such as a direct-bonded metal (DBM) substrate configured to support the components in place of the PCB or in addition to the PCB (e.g., a DBM substrate that is part of a device package of a component that is then disposed on the PCB).

In some implementations, a direct-bonded metal (DBM) substrate may be used that includes an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, the DBM substrate can be formed by bonding one or more of the metal layers (e.g., the first metal layer, the second metal layer, etc.) to the insulating layer (e.g., a ceramic layer or the like). For example, the one or more metal layers may be bonded to the insulating layer using, for example, a high-temperature process.

In some implementations, the first metal layer and/or the second metal layer can be configured to function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer may be implemented as copper layers.

In some implementations, one or more semiconductor dies can be embedded within a layer (rather than surface mounted). For example, as further described and illustrated herein, one or more semiconductor dies can be disposed within a recess or cavity of a layer (e.g., a substrate, a printed circuit board, a conductive layer, an insulating layer, etc.).

To illustrate, a set of components 104 is shown to be applied to first carrier board 102-1 prior to the joining of first carrier board 102-1 with second carrier board 102-2, so that the set of components is ultimately embedded within composite carrier board 102 (i.e., embedded between the first carrier board and the second carrier board) when composite carrier board 102 is fully assembled (i.e., by the performance of step 112-1). The set of components 104 may include any suitable electronic components, conductive components, or other elements that may serve to form the electronic circuit. A few example components that may be included within the set of components 104 will now be described.

In certain implementations, the set of components 104 may include at least one unpackaged semiconductor die. For instance, in one example, the unpackaged semiconductor die could implement an integrated circuit including a plurality of transistors (e.g., a processor or other such integrated circuit that could include a large number of transistors implementing logic, mixed signal processing, or the like).

As another example, the unpackaged semiconductor die could implement one or more power transistors (e.g., a singular power transistor) used for manipulating current that is to provide power for doing work (e.g., current that will be used in a motor of an electric vehicle or the like). These types of power transistors could be implemented, for example, by power metal-oxide-semiconductor field-effect transistors (MOSFETs) fabricated using a silicon (Si) semiconductor, a silicon carbide (SiC) semiconductor, a gallium nitride (GaN) semiconductor, or the like. In certain implementations, the set of components 104 may include a plurality of unpackaged semiconductor dies. For example, multiple power FETs (e.g., power MOSFETs) could be used to implement a half-bridge, full-bridge, or other circuit used for an automotive power inverter device. In certain implementations involving multiple semiconductor dies, the dies may be identical or may at least be fabricated using a same type of semiconductor (e.g., all the semiconductor dies being fabricated using a silicon (Si) semiconductor, all the semiconductor dies being fabricated using a silicon carbide (SiC) semiconductor, etc.). In other implementations involving multiple semiconductor dies, hybrid dies fabricated using different semiconductors may be used. For instance, the set of components 104 may include both a first semiconductor die fabricated using a silicon (Si) semiconductor and a second semiconductor die fabricated using a silicon carbide (SiC) semiconductor.

In some implementations, one or more semiconductor dies (e.g., one or more semiconductor components) included among the set of components 104 can be, or can include, a power semiconductor die. In some implementations, a semiconductor die may implement one or more transistors or a portion of a transistor or transistor-based circuit. For example, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, or the like could be implemented on a semiconductor die. In some implementations, a component implemented (or partially implemented) by one or more semiconductor dies can be used or included within an electrical vehicle (EV).

More than one semiconductor die can be included in the implementations described herein. In some implementations involving more than one semiconductor die, the different semiconductor dies can be fabricated using different semiconductor substrates (e.g., a silicon carbide (SiC) substrate, a silicon (Si) substrate, a gallium nitride (GaN) substrate, etc.). In other words, different semiconductor dies may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Among the set of components 104 included in electronic assembly 100, one or more conductive elements configured to make electrical connections between other components may be included. For instance, a first semiconductor die may be connected to a second semiconductor die by way of an electrical connection (e.g., a wire bond, an electrical clip, etc.) extending directly from the first die to the second die, or connected through a pad or trace formed in the first conductive layer (e.g., a metal layer) of an electronic power substrate. The first of the plurality of semiconductor dies may be also connected to lead frame posts by electrical connections such as wire bonds or clips. In other words, the set of components 104 may include one or more conductive clips, wire bonds, or other conductive elements configured to electrically couple semiconductor dies (e.g., unpackaged semiconductor dies) to one another and/or to other components within the electronic circuit.

One or more wire bonds, which can be included in at least some of the implementations described herein, can be replaced with other types of conductive elements. For example, in some implementations, one or more wire bonds can be replaced with a conductive clip. The conductive clip can be coupled to another component (e.g., an attach pad, a leadframe, a semiconductor die, etc.) using, for example, a solder (e.g., a soldering process), a sintered coupling (e.g., a sintering process), a weld, or the like. In some implementations, one or more wire bonds and/or clips can function as an input and/or output power terminal, a signal terminal, a power terminal, or another suitable terminal.

The set of components 104 may be connected to conductive elements (e.g., clips or wire bonds; pads of a PCB, DBM substrate or other suitable carrier board; etc.) using any suitable electrical connection or joint as may serve a particular implementation. For instance, soldering, sintering, adhesive mechanisms, and/or other suitable ways of connecting electronic components may be used.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder or solder material.

In some implementations, sintering can be or can include a process of fusing particles together into one solid mass by using, for example, a combination of pressure and/or heat that is applied without melting the materials. In some implementations, sintering can include making a material (e.g., a powdered sintering material) coalesce into a solid or porous mass by heating the material (as well as, in some cases, compressing the material) without liquefaction. In some implementations, materials that can be used for sintering include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder material, a sintering material (e.g., silver, copper), and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

Electronic circuit packaging may typically include applying a molding compound (e.g., molding material or compound, an encapsulation material) around a circuit to protect the circuit with this non-conducting layer/material. For instance, a molding compound could be a non-conducting material that can be formed (applied, etc.) using a transfer molding process or a compression molding process. The molding material may be or include an organic material (e.g., a polymer or plastic material such as epoxy, silicone, phenolic resin, etc.), an inorganic material (e.g., a non-conductive ceramic or conductive metal material, etc.), and/or other suitable materials as may serve a particular implementation. In some implementations, the molding compound can include a separate plastic housing that is included in the semiconductor device assembly.

In some implementations, however, these molding techniques may not be necessary for assemblies such as electronic assembly 100 shown in FIG. 1. This is because the set of components 104 may be fully protected and enclosed by the composite carrier board 102 (i.e., by the joining of first carrier board 102-1 to second carrier board 102-2). In other implementations, certain molding techniques (e.g., for individual components included among set of components 104, etc.) may still be employed in accordance with principles described herein.

The plurality of leads 108 may be integrated with composite carrier board 102 and configured to provide external access to a plurality of circuit nodes of the electronic circuit. For example, different nodes of the electronic circuit such as pads of the unpackaged semiconductor dies, nodes associated with certain conductive elements such as clips or wires, pads and/or vias of PCBs implementing first carrier board 102-1 and/or second carrier board 102-2, and so forth, may be exposed to external circuitry by leads 108 that connect to the elements and extend out of composite carrier board 102 as shown.

In some examples, the leads 108 may be constructed or added to electronic assembly 100 as part of a leadframe. Although referred to, by way of example, as a leadframe in at least some portions of this detailed description, leadframes described herein may include any type of conductive portion of a package (e.g., conductive portion, conductive terminal, etc.) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate, a PCB, or another suitable carrier board described herein. Semiconductor device packages described herein may include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

Immersive cooling assembly 110 may be assembled around the fully assembled composite carrier board 102 (with the set of components 104 of the electronic circuit fully embedded) to at least partially enclose the composite carrier board 102. Additionally, as shown by port 114, immersive cooling assembly 110 may include an inlet port (for fluid intake) and an outlet port (for fluid release), only one of which (port 114) is shown in FIG. 1. As cooling fluid is pumped into the inlet port while being released and circulated out of the outlet port, immersive cooling assembly 110 may be configured to guide the cooling fluid over composite carrier board 102. In this way, the cooling fluid may draw heat away from the composite carrier board 102 as the electronic circuit produces heat that could otherwise (if not drawn away and dissipated) present issues for the electronic assembly 100.

While not explicitly shown in FIG. 1, it will be understood that spacer material could be used within electronic assembly 100, such as between the respective carrier boards 102-1 and 102-2 (when they are joined together), between immersive cooling assembly 110 and composite carrier board 102, or elsewhere. In some implementations, a spacer material may be included between certain elements of the apparatus such as between a leadframe and a substrate, between a semiconductor die and a substrate, between the apparatus and a substrate, or the like. Such spacer material can be or can include an epoxy, a silicone adhesive, a conductive material, a non-conductive material, an organic material, a semiconductor material, a metal alloy, a metal foam, a phase change material, or the like.

In some implementations, a module (e.g., an apparatus including a semiconductor device within a package) can be included in another module. The module can be referred to as a package. For example, one or more modules can be one or more sub-modules included within another module. In other words, a first module can be included as a sub-module within a second module. Referring more particularly to modules such as are implemented by electronic assembly 100, these may serve as sub-modules to a larger module such as a circuit, system, or device that employs electronic assembly 100 and may include a plurality of instances of electronic assembly 100.

As mentioned above, one specific application for an electronic assembly such as electronic assembly 100 may be for a power inverter assembly (e.g., a power inverter assembly configured for use in an automotive application). For example, for this type of implementation, the power inverter assembly may include a first printed circuit board (PCB) and a second PCB implementing, respectively, the first carrier board 102-1 and the second carrier board 102-2. The first PCB may be joined to the second PCB to form a composite PCB implementing the composite carrier board 102. The power inverter assembly may further include a set of components forming a power inverter circuit. The set of components may implement the set of components 104 and may include a plurality of unpackaged semiconductor dies each implementing singular power transistors. The set of components may be embedded within the composite PCB between the first PCB and the second PCB as described for components 104 in relation to FIG. 1.

The power inverter assembly in this example may further include a plurality of leads integrated with the composite PCB and configured to provide external access to a plurality of circuit nodes of the power inverter circuit. This plurality of leads may implement the plurality of leads 108 described above for this example. The power inverter assembly may also include an immersive cooling assembly implementing the immersive cooling assembly 110 and being specifically configured (e.g., by virtue of its shape, the characteristics of its materials, etc.) for use in an automotive application in this example. The immersive cooling assembly may at least partially enclose the composite PCB and may be configured to guide a cooling fluid over the composite PCB.

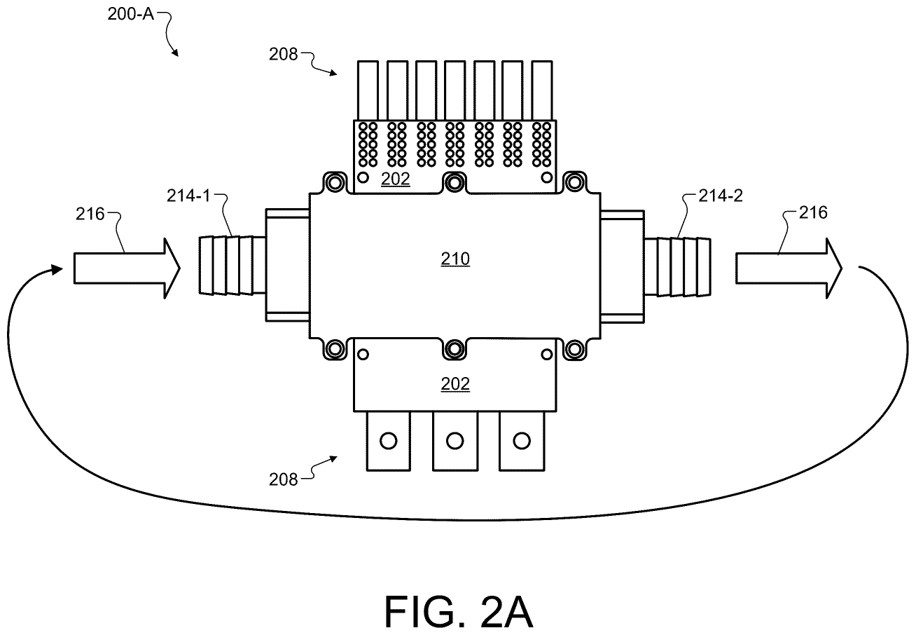

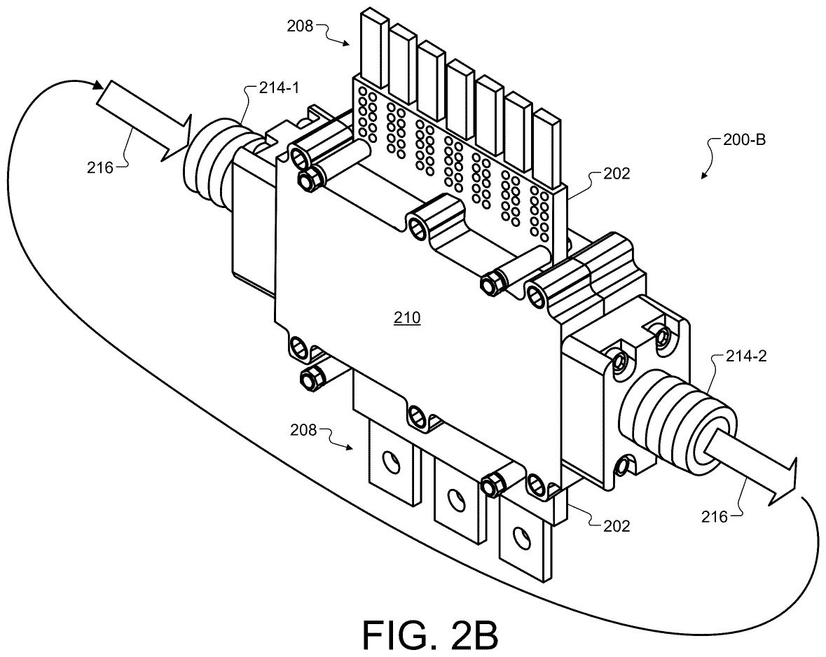

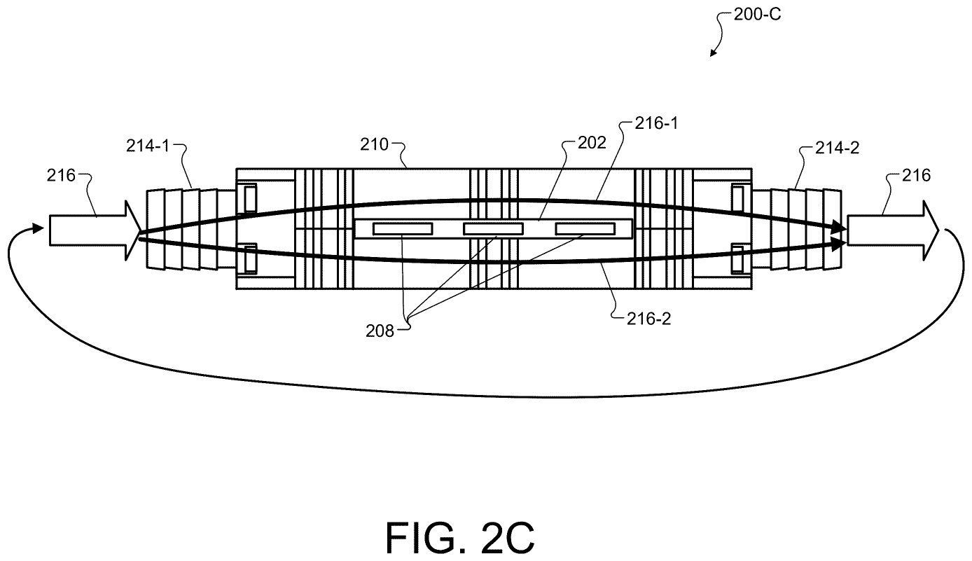

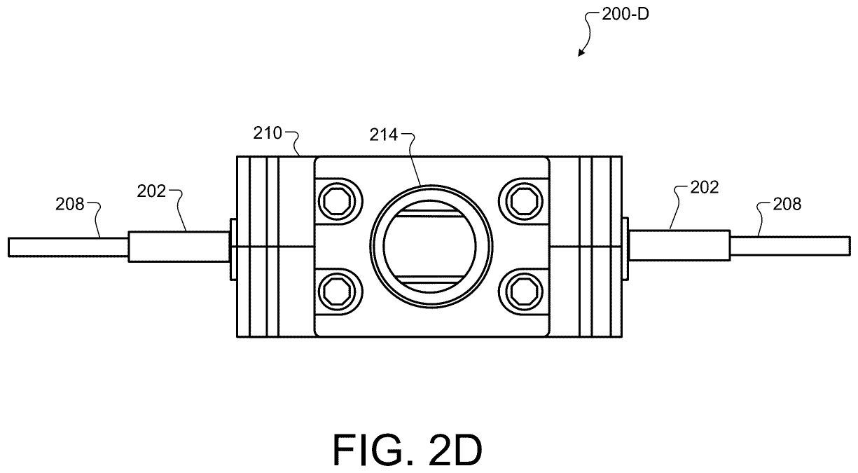

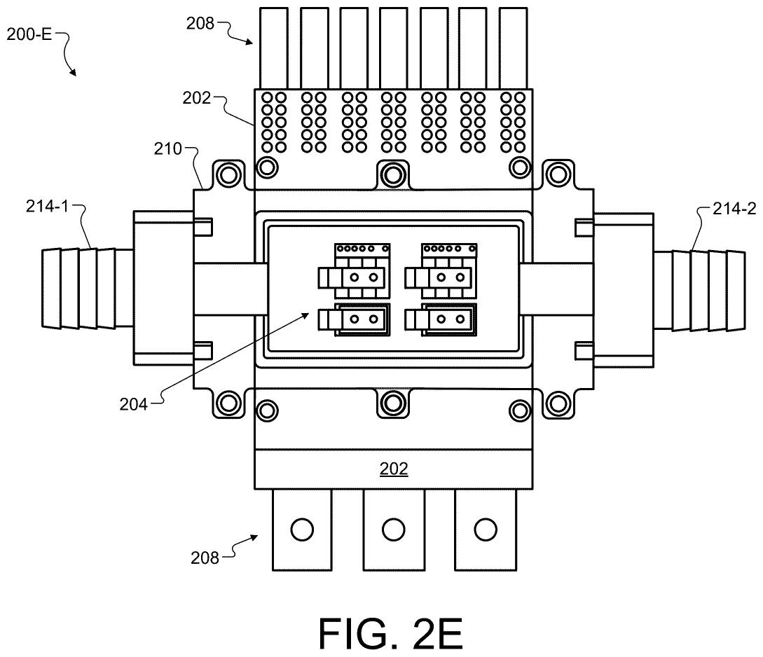

To illustrate, FIGS. 2A-2E show an illustrative implementation of a power inverter assembly that, as described above, implements electronic assembly 100 and is configured to perform immersion cooling of embedded electronic components in the context of an automotive power inverter. In FIGS. 2A-2E, the example power inverter assembly is shown from a variety of views to illustrate a variety of aspects of the assembly in accordance with principles described herein. While this implementation is described as implementing the elements of electronic assembly 100 in particular ways (e.g., with the carrier boards being implemented by PCBs, the semiconductor dies being implemented by singular transistor dies, the electronic circuit being implemented by a power inverter circuit, etc.), it will be understood that these same elements may be implemented in other ways for other implementations. For example, carrier boards could be implemented by other types of substrates or carriers that are not PCBs, the semiconductor dies could be implemented by other types of components that are not singular transistors, the electronic circuit could be implemented by circuits configured to perform functions other than power inverter functions, and so forth.

FIG. 2A shows a front view 200-A of the power inverter assembly in a fully assembled form (comparable to the assembled electronic assembly 100 described above). This power inverter assembly is referred to herein as power inverter assembly 200 and will be shown from various different views 200-A through 200-E in FIGS. 2A-2E.

Corresponding reference numbers are used in FIG. 2A and other figures below to indicate corresponding elements of the assembly. For example, front view 200-A shows that power inverter assembly 200 includes a composite PCB 202 corresponding to the composite carrier board 102 described in relation to FIG. 1, and other examples below similarly use reference numbers with ending with ‘02’ (or ‘02-1’, ‘02-2’, etc., when only one part of the composite board is referred to) to indicate an implementation of a carrier board such as a PCB. Power inverter assembly 200 will be understood to incorporate, within the composite PCB 202, a set of components 204 corresponding to the set of components 104 and electrical connections corresponding to the electrical connection 106. These elements are not explicitly illustrated in front view 200-A, since they are occluded by other elements of the assembly, but will be depicted in other views below. Front view 200-A of power inverter assembly 200 does show, however, a plurality of leads 208 corresponding to the plurality of leads 108 described above, as well as an assembled immersive cooling assembly 210 corresponding to the immersive cooling assembly 110 of electronic assembly 100.

Composite PCB 202 is shown to include various vias allowing access to certain leads 208 at the top of the assembly. These leads may be used for certain control signals and/or other relatively low-power signaling (e.g., gate signals, sensor signals, etc.) for the power inverter circuit as may serve a particular implementation. Different implementations may access these leads in different ways (e.g., directly by way of the leads, by way of an insert board that connects by way of press-fit pins and press-fit sockets to the vias, etc.), as will be described and illustrated in more detail below. Additional (larger) leads 208 are also shown to be included at the bottom of the assembly. For the power inverter circuit implementation, these leads 208 will be understood to represent leads configured to handle larger voltages and/or currents associated with the power inverter function of the circuit. For example, these pins could include a positive DC input lead (DC+), a negative DC (or ground) input lead (DC−), and an AC output lead (AC) in one example.

Along with the various elements corresponding directly to those elements described above in relation to electronic assembly 100, power inverter assembly 200 is shown to further include other elements. For example, power inverter assembly 200 is shown to include an input port 214-1 into which cooling fluid 216 may be introduced and an output port 214-2 from which the cooling fluid 216 may be expelled. As will be further described and illustrated in relation to other views of power inverter assembly 200 below, inlet port 214-1 may be configured to intake cooling fluid 216 (e.g., when the fluid is at a relatively low temperature) and outlet port 214-2 may be configured to release cooling fluid 216 (e.g., after the fluid has drawn heat away from the power inverter circuit of the composite PCB 202 and is therefore at a relatively high temperature).

FIG. 2B shows a perspective view 200-B of power inverter assembly 200. The same elements are labeled in perspective view 200-B as described above in relation to front view 200-A, though certain additional details are visible from the perspective view. For example, the cylindrical nature of ports 214-1 and 214-2 are more apparent in perspective view 200-B as the cooling fluid 216 is cycled through, an example thickness of composite PCB 202 and leads 208 is illustrated more clearly, additional details relating to the construction and assembly of immersive cooling assembly 210 are shown (e.g., screws and other fastening mechanisms, etc.), and so forth.

FIG. 2C shows a bottom view 200-C of power inverter assembly 200 (i.e., looking up at the three leads 208 shown to be extending from the bottom of composite PCB 202 as the PCB is oriented in views 200-A and 200-B). The same elements as labeled in front view 200-A and perspective view 200-B are again labeled in bottom view 200-C, though bottom view 200-C further shows how fluid 216 may be guided over both sides of composite PCB 202 in some implementations. More particularly, as shown, immersive cooling assembly 210 may be configured to guide some of the cooling fluid 216 (labeled as cooling fluid 216-1 in FIG. 2C) over a first surface of the composite carrier board (e.g., over a first surface of composite PCB 202 in this example) while also guiding other cooling fluid 216 (labeled as cooling fluid 216-2 in FIG. 2C) over a second surface of the composite carrier board opposite the first surface (e.g., over the opposite surface of composite PCB 202 in this example).

By guiding cooling fluid over both surfaces of the carrier board, as shown, power inverter assembly 200 may cool the circuit more effectively and efficiently than it would if guiding cooling fluid over only a single surface. As has been described, since the carrier board (e.g., composite PCB 202 in this example) incorporates and protects the electronic circuit (e.g., the power inverter circuit) acting as the primary source of heat that is to be removed/dissipated, an immersive cooling assembly configured to simultaneously draw heat away from both sides of the board as the heat is produced during operation may be highly effective and provide various advantages described herein.

FIG. 2D shows a side view 200-D of power inverter assembly 200. Insofar as they are not occluded from view, the same elements are again labeled in side view 200-D as have been labeled and described in relation to other views above, including a particular port 214 that could represent either of ports 214-1 or 214-2 (depending on which side is being viewed). Certain additional details are easier to see from side view 200-D than in other views.

FIG. 2E shows a cutaway view 200-E of power inverter assembly 200. Along with other elements that have been illustrated and described in relation to other views of power inverter assembly 200, cutaway view 200-E further shows the set of components 204 mentioned above (corresponding to the set of components 104 described in relation to electronic assembly 100), which may be configured to form a power inverter circuit. While illustrated in the cutaway view 200-E, it will be understood that components 204 may be embedded within the composite PCB 202 (e.g., between a first PCB and a second PCB) so as to be protected from cooling fluid that may be guided over both sides of the composite PCB 202 by immersive cooling assembly 210.

The set of components 204 may include one or more semiconductor dies, one or more conductive elements (e.g., wire, clips, etc.), other discrete components (e.g., capacitors, resistors, etc.), and/or any other electronic components or other circuit elements as may serve a particular implementation. As mentioned above in relation to the set of components 104, the set of components 204 may include at least one unpackaged semiconductor die, such as a die implementing a singular power transistor (e.g., a power MOSFET fabricated using a silicon (Si) or silicon carbide (SiC) semiconductor). Multiple such dies (i.e., multiple power transistors) may be interconnected within the circuit formed by the set of components 204 to create a half-bridge circuit, a full-bridge circuit, or other suitable power inverter circuitry. The set of components 204 may further include at least one conductive clip configured to electrically couple unpackaged semiconductor dies to one another (and/or to other components) within the power inverter circuit. In certain implementations, a hybrid die configuration may be used (e.g., the set of components 204 may include a plurality of unpackaged semiconductor dies including a first semiconductor die fabricated using a silicon (Si) semiconductor and a second semiconductor die fabricated using a silicon carbide (SiC) semiconductor).

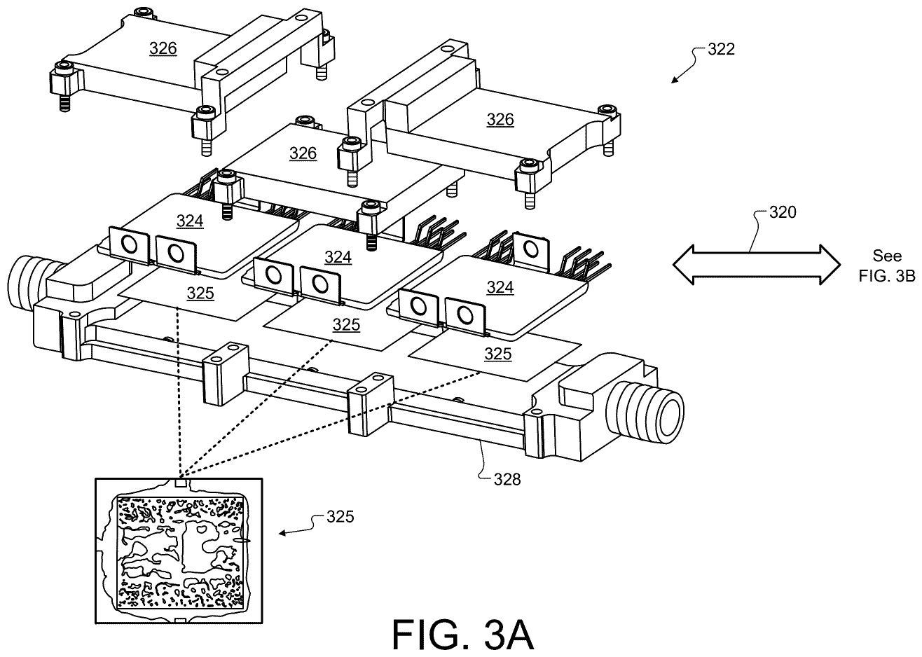

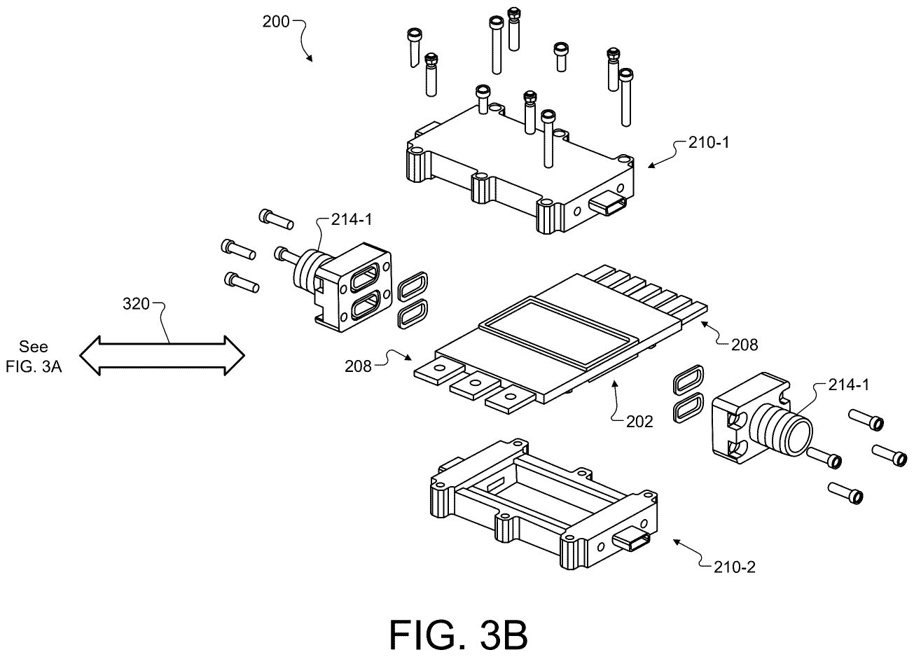

FIGS. 3A-3B contrast certain aspects of a conventional cooling system for electronic components and an electronic assembly configured to perform immersion cooling of embedded electronic components in accordance with principles described herein. More particularly, a contrast 320 is shown to illustrate certain differences between a conventional cooling system 322 and the power inverter assembly 200 that has been presented as leveraging novel principles described herein.

In both FIGS. 3A and 3B, exploded views of the respective cooling systems are shown. In the exploded view of conventional cooling system 322, for example, multiple electronic apparatuses 324 are shown each have one side physically coupled, by way of respective solder pads 325 and cover plates 326, to a surface of an active cooler 328. As shown, active cooler 328 includes ports (similar to ports 214-1 and 214-2 of power inverter assembly 200) into which cooling fluid may be introduced and removed. Despite these similarities, one point of contrast illustrated by contrast 320 is that active cooler 328, not being an immersive cooling assembly like immersive cooling assembly 210, is only able to draw heat away from one surface of the multiple electronic apparatuses 324, rather than both surfaces. As has been mentioned, this may be less effective and efficient than simultaneously drawing heat away from both sides as immersive cooling assembly 210 is shown to be able to do (since each port is shown to be associated with two fluid paths associated with the top and bottom surfaces of the composite PCB 202).

As another point of contrast illustrated by contrast 320, a closeup view of one of the respective solder pads 325 is shown at the bottom of FIG. 3A to illustrate how small voids and imperfections in the solder layer may lead to lower thermal performance by impeding the transfer of heat from the multiple electronic apparatuses 324 to the surface of the active cooler 328. As mentioned above and as shown in the exploded view of FIG. 3B, in contrast, power inverter assembly 200 does not rely on solder pads to couple a first portion 210-1 and a second portion 210-2 of the immersive cooling assembly 210 with the composite PCB 202. As such, power inverter assembly 200 avoids the undesirable voids and heat transfer inhibition that such solder pads may introduce. The immersive nature of the assembly and the fact that the composite PCB 202 is tightly enclosed within the assembly removes any need for a layer of solder and the potential thermal issues that could be introduced thereby.

As yet another point of contrast illustrated by contrast 320, fluid flowing through active cooler 328 is separated from the electronic apparatuses 324 by the top surface of the active cooler 328, as well as by the respective solder pads 325. In contrast, as has been described, cooling fluid guided through immersive cooling assembly 210 may be in direct contact with composite PCB 202. As the PCB itself may be configured to serve as an efficient conductor of heat (superior to, for example, the solder pads 325 with their voids and imperfections as illustrated in FIG. 3A), and as the PCB may incorporate otherwise unpackaged components (e.g., semiconductor dies, etc.) that present no other impediments to heat transfer, the transfer of heat into the cooling fluid may be highly effective and efficient in the case of power inverter assembly 200 as compared to the case of conventional cooling system 322.

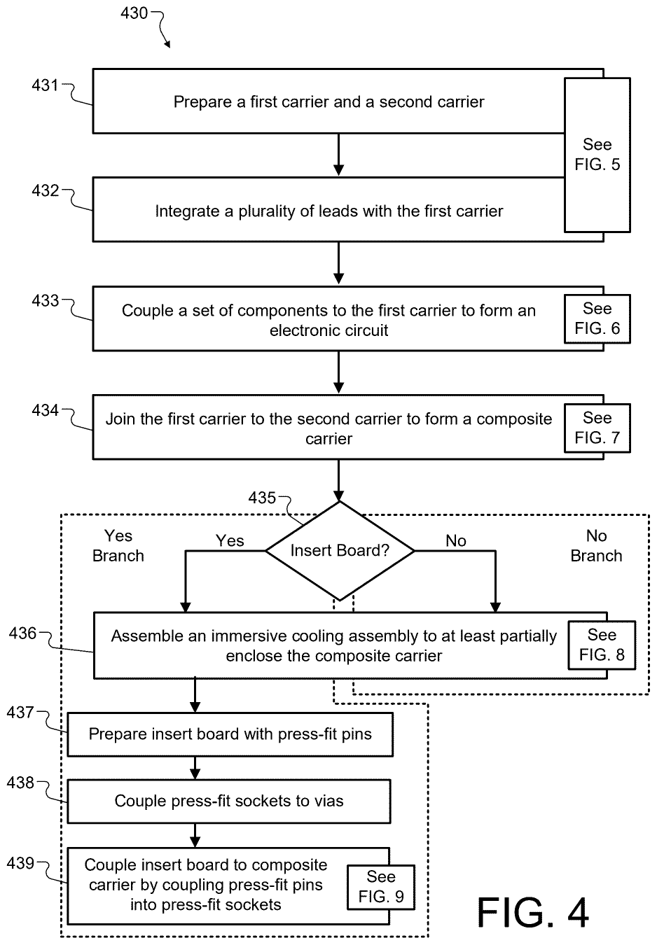

FIG. 4 shows an illustrative method 430 for constructing an electronic assembly configured to perform immersion cooling of embedded electronic components in accordance with principles described herein. For example, an electronic assembly such as an implementation of electronic assembly 100 (e.g., power inverter assembly 200 or another suitable implementation) may be assembled or constructed based on the steps of method 430. While FIG. 4 shows illustrative operations 431-439 according to one implementation, other implementations of method 430 may omit, add to, reorder, and/or modify any of the operations 431-439 shown in FIG. 4. In some examples, multiple operations shown in FIG. 4 or described in relation to FIG. 4 may be performed concurrently (e.g., in parallel) with one another, rather than being performed sequentially as illustrated and/or described.

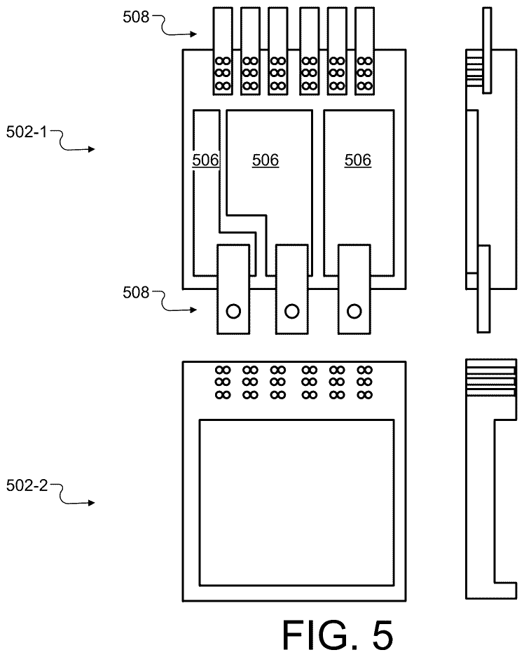

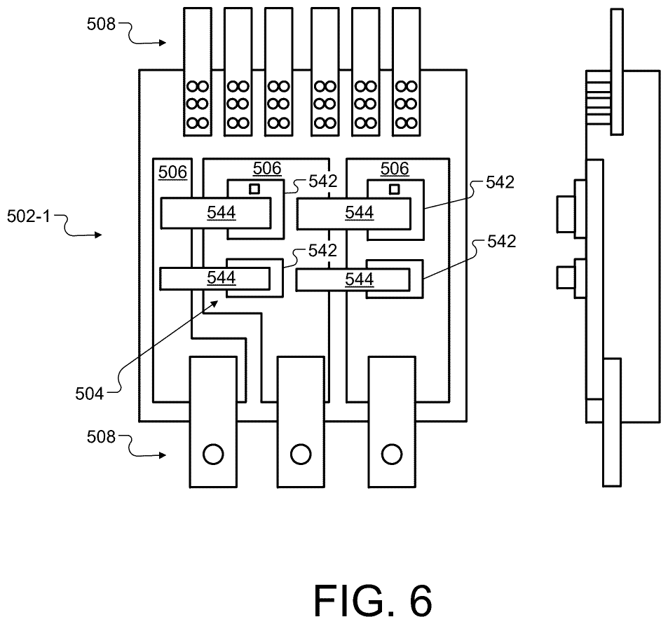

Each of operations 431-439 will now be described in more detail. As indicated in tags attached to certain operations in FIG. 4 (e.g., “See FIG. 5,” “See FIG. 6,”, etc.), certain aspects of some of the operations of illustrative method 430 are further illustrated in, and described with reference to, FIGS. 5-9.

At operation 431, a first carrier and a second carrier may be prepared for use in the electronic assembly. For example, the first and second carriers (also referred to as carrier boards) may correspond to first carrier board 102-1 and second carrier board 102-2, respectively, and may be implemented by any of the carrier boards described herein (e.g., PCBs, DBM substrates, etc.). The first and second carrier boards may be prepared at operation 431 by being constructed or otherwise obtained in any suitable manner (e.g., by procuring pre-fabricated PCBs from a supplier entity, etc.). In some implementations, the carrier boards may be implemented by PCBs that are designed to incorporate electrical connections configured to interconnect various components disposed on (between) the PCBs to thereby form an electronic circuit. Designs for such PCBs may be fabricated by printing (e.g., depositing, etching, etc.) various conductive layers (e.g., copper layers, etc.) onto insulative (e.g., dielectric) layers of material to form the PCBs. In some cases, the boards may be procured by providing designs for the first and/or second carrier boards to a supplier (e.g., a board fabrication entity) that provides services including manufacturing carrier boards to order.

While preparation of both carrier boards is shown to be included as part of operation 431, it will be understood that the first and second carrier boards may be fabricated separately and/or at different times. Additionally, it will be understood that the two carrier boards may be identical or may have significant differences. For instance, the first carrier board may include various pads, traces, and other conductive elements to provide electrical connections for components that are to be applied to the first carrier board, while the second carrier board may not include these elements. On the other hand, the second carrier board could have different conductive elements to provide different electrical connections. Additionally, either or both of the first and second carrier boards may include vias, as will be described and illustrated in more detail below.

At operation 432, a plurality of leads may be integrated with the first carrier. For example, a set of leads such as described in relation to leads 108 and/or leads 208 may be included as part of the carrier, coupled to the carrier, or otherwise integrated as part of the carrier. Additionally, a plurality of vias configured to provide access to this plurality of leads may be formed, within the first and/or second carrier boards as part of operation 432 or operation 431. To illustrate the preparation of the carrier boards with their integrated leads and vias providing access to the leads, reference is made to FIG. 5.

As shown, FIG. 5 depicts illustrative aspects related to preparing the first and second carrier boards with their plurality of leads for the electronic assembly being constructed by method 430. In FIG. 5, a carrier board 502-1 represents a first PCB that may be prepared (e.g., constructed, designed and procured, etc.) to serve as the first carrier board, while a carrier board 502-2 represents a second PCB that may be similarly prepared (e.g., constructed, ordered and obtained, etc.) to serve as the second carrier board. Both carrier boards are shown in FIG. 5 both from a front view (on the left in the figure) and from a side view (on the right in the figure).

Integrated with the carrier board 502-1, FIG. 5 shows a plurality of leads 508 on the top and bottom of the board and that will be understood to be similar to leads 208 described above. Vias represented by small circles in the front view and by narrow channels in the side view are also shown to provide access to some of the leads 508. Additionally, certain electrical connections 506 (e.g., conductive power pads applied on top of an insulative layer of the board, etc.) are shown to be included (and selectively coupled with certain leads 508) in preparation for components to be coupled to the carrier board. These power pads may be configured for semiconductor dies to be mounted and to serve as current paths for signals with significant amounts of current. Conductive inlays (e.g., copper inlays) may be included within the board and used to implement some or all of leads 508, as well as other signal pins, current paths, power terminals, or the like.

Carrier board 502-2 is also shown in FIG. 5, though, as mentioned above, this carrier board could be constructed separately (e.g., at a different time, ordered from a different supplier, etc.) from carrier board 502-1 in certain cases. Carrier board 502-2 is also shown to include vias configured to provide access (through the second carrier board) to the leads 508 integrated with the first carrier board (i.e., carrier board 502-1). Additionally or alternatively, certain gate and sensor paths (e.g., traces) could be integrated in this second carrier board that are distinct from the power paths incorporated in the first carrier board. In this example, a concave area of carrier board 502-2 is shown to be included to help accommodate components coupled to carrier board 502-1 when the two carrier boards 502-1 and 502-2 are joined together into a single composite carrier board (as will be described and illustrated in more detail below). In some example, a spacer or filler material may be included between the carrier boards when joined together to promote more efficient heat transfer, less vibration of the components, and so forth.

Returning to FIG. 4, at operation 433, a set of components may be coupled to the first carrier board to form (e.g., possibly in connection with electrical connections provided by at least the first carrier board) an electronic circuit. The electronic circuit may include a plurality of circuit nodes that are externally accessible by way of the plurality of leads and/or vias that were prepared and integrated into the carrier boards at operations 431 and 432. The components coupled to the first carrier board at operation 433 may include any of the components as have been described herein. As one example, the set of components may include unpackaged semiconductor dies implementing singular power transistors (e.g., power FETs, etc.) that are combined with clips or other conductive elements to form a power inverter circuit such as has been described.

To illustrate, FIG. 6 shows certain aspects related to coupling components to carrier board 502-1 in accordance with principles described herein. As shown in FIG. 6, the same carrier board 502-1, electrical connections 506, and leads 508 described above are still present, while certain components 504 have been added to the assembly. As shown, these components 504 include unpackaged semiconductor dies 542 that are coupled directly to the power pads (i.e., electrical connections 506), as well as clips 544 that are coupled between pads of the semiconductor dies and the power pads of electrical connections 506 (to thereby form additional electrical connections). As shown in the side view, the components coupled to the first carrier board 502-1 at operation 433 change the profile of carrier board 502-1 such that the concave area mentioned above to be included in carrier board 502-2 may be helpful to accommodate the components while still sealing off the circuit from the external environment (e.g., including from cooling fluid that may be guided over the composite carrier board).

Returning to FIG. 4, at operation 434, the first carrier may be joined to the second carrier to form a composite carrier. For example, operation 434 may be performed subsequent to the coupling of the set of components to the first carrier board at operation 433 such that, when the boards are joined and the composite carrier board is formed, the electronic circuit (including all the components certain components 504) are embedded within the composite carrier board (i.e., in the concave area between the two carrier boards.

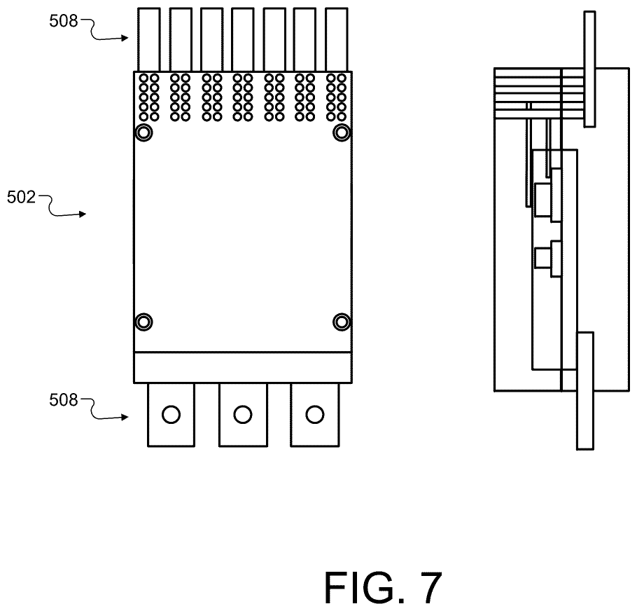

To illustrate, FIG. 7 shows illustrative aspects related to joining two carrier boards to form a composite carrier board with an embedded electronic circuit in accordance with principles described herein. More particularly, FIG. 7 shows a composite carrier board 502 with protruding leads 508 that is formed when, as shown by the side view on the right side of the figure, the carrier board 502-1 and the carrier board 502-2 are joined. This side view will be understood to be showing a cutaway view so that the embedded electronic components are visible. Without the cutaway, however, it will be understood that these components may be fully embedded and sealed (e.g., protected from the external environment) between the carrier boards. The joining of the first and second carrier boards to form composite carrier board 502 may involve heating the boards, putting the boards under pressure, reflowing or otherwise activating a connective material between the boards (e.g., solder, sintering material, epoxy, etc.), and/or other suitable joining techniques.

Returning to FIG. 4, operation 435 represents a decision point in method 430 in which it is determined whether an additional carrier board (referred to herein as an insert board) may be desired for the assembly being constructed. For certain applications, an insert board (e.g., an additional PCB, etc.) that is connected to the various leads (e.g., by way of pins and vias as will be described in more detail below) may be helpful for exposing the circuitry to external elements that are to control and/or be controlled by the circuitry. For example, if a legacy assembly was configured to connect to another apparatus by lying flat on the apparatus, the presence of an immersive cooling assembly that encloses at least part of the composite carrier board may interfere with the board lying flat on the apparatus and/or otherwise coupling to other components in a desirable way. In such cases, an insert board that remains external to the immersive cooling assembly while electrically coupling to the composite carrier board (which is internal to the immersive cooling assembly) may be useful for facilitating various physical and/or electrical couplings of the assembly. For these situations, operation 435 may resolve to “Yes” and the flow of method 430 may proceed into a “Yes Branch” that includes operations 436-439, as shown.

Conversely, other applications may not require the same type of access or otherwise may lack any real utility for an external insert board such as described above. For instance, these implementations may utilize other configurations for physically and/or electrically coupling the electronic assembly to external apparatuses. In these cases, an insert board that is external to the immersive cooling assembly while being coupled to the composite carrier board would therefore not provide any particular advantage and operation 435 may resolve to “No.” The flow of method 430 may then proceed into a “No Branch” that includes only operation 436 and then terminates, as shown.

It will be understood that the Yes and No Branches associated with operation 435 (and labeled in FIG. 4) result in the construction of two different variations of electronic assembly 100. First, the Yes Branch may result in a composite carrier board that includes a plurality of vias configured to provide access to the plurality of leads and an electronic assembly that further comprises a plurality of press-fit sockets configured to provide access to the plurality of vias. Conversely, the No Branch may result in a composite carrier board that includes a plurality of vias configured to provide access to the plurality of leads without press-fit sockets to provide access to the plurality of vias. In other words, as illustrated by power inverter assembly 200 in views 200-A through 200-E, the electronic assembly may include the composite carrier board and the immersive cooling assembly without an additional insert board. The various operations of the Yes and No Branches will each now be described.

Operation 436 is shown to be performed as part of both the Yes Branch and the No Branch subsequent to operation 435. At operation 436, an immersive cooling assembly may be assembled to at least partially enclose the composite carrier board formed at operation 434. As has been described and illustrated, the immersive cooling assembly may include an inlet port configured to intake cooling fluid and an outlet port configured to release the cooling fluid. The immersive cooling assembly assembled to enclose the composite carrier board at operation 436 may be configured to guide the cooling fluid over the composite carrier board. In certain implementations, as has further been described, the immersive cooling assembly may be configured to guide the cooling fluid over both: 1) a first surface of the composite carrier board, and 2) a second surface of the composite carrier board opposite the first surface.

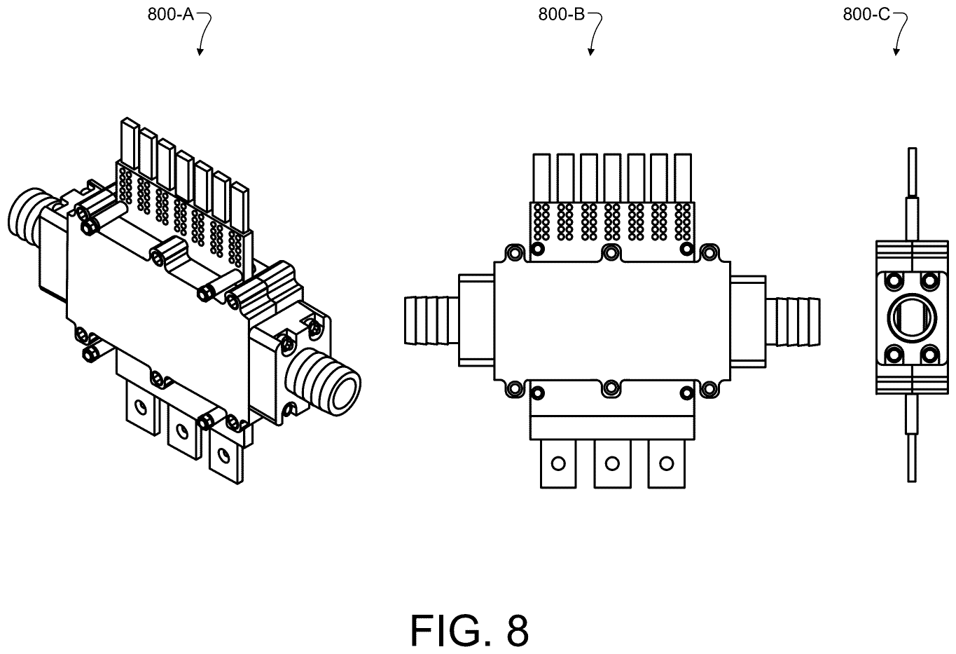

To illustrate operation 436, FIG. 8 shows certain aspects of this type of electronic assembly (without an insert board being included at all or being added yet). More particularly, FIG. 8 shows a perspective view 800-A of a complete electronic assembly (i.e., a finished product of method 430 in the event that the No Branch is selected). A front view 800-B shows the same electronic assembly from the front (analogous to front view 200-A described above), while a side view 800-C shows the same electronic assembly from the side (analogous to side view 200-D described above). If the No Branch is selected, operation 436 will be understood to be the final operation of method 430 and the electronic assembly shown in views 800-A through 800-C will be understood to represent the completed assembly (i.e., no press-fit sockets nor insert board are to be included in the assembly in this case). Conversely, if the Yes Branch is selected, views 800-A through 800-C will be understood to represent the electronic assembly at an intermediate step before press-fit sockets and the insert board are added.

Returning to FIG. 4 and continuing with the operations of the Yes Branch, operation 437 is shown to involve preparing an insert board with a plurality of press-fit pins that are configured to couple with a plurality of press-fit sockets that, at operation 438, are coupled to the plurality of vias of the composite carrier board. These press-fit pins and sockets may provide access (for the insert board or other elements connected thereto) to the plurality of vias, and thereby to the leads and/or relevant circuit nodes, as has been described. As described above, the insert board may include a plurality of press-fit pins configured to couple with a plurality of press-fit sockets. Alternatively, the press-fit sockets could be included on the insert board with the pins coupled to the vias on the composite carrier board. In either case, the insert board may be configured to couple to the composite carrier board by way of a coupling between the plurality of press-fit pins and the plurality of press-fit sockets, and may be configured to be external to the immersive cooling assembly when the insert board is coupled to the composite carrier board.

At operation 439 (still within the Yes Branch), the insert board may be coupled to the composite carrier board by coupling the plurality of press-fit pins and the plurality of press-fit sockets. As has been described, the insert board may be external to the immersive cooling assembly when this coupling between the insert board and the composite carrier board is performed. The press-fit pins/sockets or another suitable connection mechanism may be long or wide enough to allow for this to be the case (i.e., for the insert board to connect to the composite carrier board while remaining external to the immersive cooling assembly).

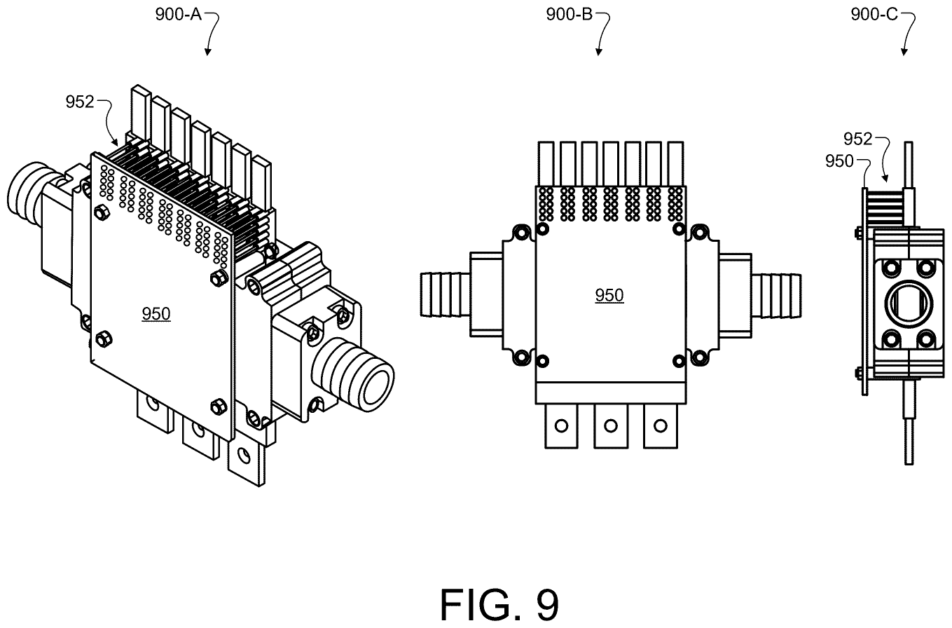

To illustrate, FIG. 9 shows illustrative aspects of this latter type of electronic assembly that can be fabricated using method 430 (i.e., when an insert board is desired and the Yes Branch is selected at operation 435). FIG. 9 includes a perspective view 900-A of the electronic assembly that corresponds to perspective view 800-A, a front view 900-B that corresponds to front view 800-B, and a side view 900-C that corresponds to side view 800-C. However, as shown from the various angles, this implementation of the electronic assembly is depicted to include an insert board 950 that is external to the immersive cooling assembly and is coupled, by way of press-fit pins and sockets 952, to the composite carrier board. As described above, the press-fit pins and sockets 952 may be respectively coupled in either orientation (i.e., with pins on the inert board and sockets on the composite carrier board or vice versa) and/or may be replaced by other suitable mechanisms that allow for the insert board 950 to electrically connect to the composite carrier board while remaining external to the immersive cooling assembly.

The following examples describe implementations (e.g., electronic assemblies, methods of construction, devices, apparatuses, etc.) of immersion cooling of embedded electronic components in accordance with principles described herein.

Example 1: An electronic assembly comprising: a first carrier and a second carrier, the first carrier being joined to the second carrier to form a composite carrier; a set of components forming an electronic circuit, the set of components being embedded within the composite carrier between the first carrier and the second carrier; a plurality of leads integrated with the composite carrier and configured to provide external access to a plurality of circuit nodes of the electronic circuit; and an immersive cooling assembly at least partially enclosing the composite carrier and configured to guide a cooling fluid over the composite carrier.

Example 2: The electronic assembly of any of the preceding examples, wherein the immersive cooling assembly is configured to guide the cooling fluid over a first surface of the composite carrier and over a second surface of the composite carrier opposite the first surface.

Example 3: The electronic assembly of any of the preceding examples, wherein: the first carrier is a first printed circuit board (PCB); the second carrier is a second PCB; and the electronic circuit includes an electrical connection provided by the first PCB, the electrical connection including a first pad, a second pad, and a trace connecting the first pad and the second pad within the first PCB.

Example 4: The electronic assembly of any of the preceding examples, wherein the immersive cooling assembly includes an inlet port configured to intake the cooling fluid and an outlet port configured to release the cooling fluid.

Example 5: The electronic assembly of any of the preceding examples, wherein the set of components includes an unpackaged semiconductor die.

Example 6: The electronic assembly of any of the preceding examples, wherein the unpackaged semiconductor die implements a singular power transistor.

Example 7: The electronic assembly of any of the preceding examples, wherein the singular power transistor is a power metal-oxide-semiconductor field-effect transistor (MOSFET) fabricated using a silicon carbide (SiC) semiconductor.

Example 8: The electronic assembly of any of the preceding examples, wherein the set of components further includes a conductive clip configured to electrically couple the unpackaged semiconductor die to another component within the electronic circuit.

Example 9: The electronic assembly of any of the preceding examples, wherein the unpackaged semiconductor die implements an integrated circuit including a plurality of transistors.

Example 10: The electronic assembly of any of the preceding examples, wherein the set of components includes a plurality of unpackaged semiconductor dies including a first semiconductor die fabricated using a silicon (Si) semiconductor and a second semiconductor die fabricated using a silicon carbide (SiC) semiconductor.

Example 11: The electronic assembly of any of the preceding examples, wherein: the composite carrier includes a plurality of vias configured to provide access to the plurality of leads; and the electronic assembly further comprises a plurality of press-fit sockets configured to provide access to the plurality of vias.

Example 12: The electronic assembly of any of the preceding examples, further comprising an insert board with a plurality of press-fit pins configured to couple with the plurality of press-fit sockets, wherein: the insert board is configured to couple to the composite carrier by way of a coupling between the plurality of press-fit pins and the plurality of press-fit sockets; and the insert board is configured to be external to the immersive cooling assembly when the insert board is coupled to the composite carrier.

Example 13: The electronic assembly of any of the preceding examples, wherein the composite carrier includes a plurality of vias configured to provide access to the plurality of leads without press-fit sockets to provide access to the plurality of vias.

Example 14: The electronic assembly of any of the preceding examples, wherein the electronic assembly implements a power inverter assembly configured for use in an automotive application.

Example 15: A method comprising: integrating a plurality of leads with a first carrier; coupling a set of components to the first carrier, the set of components forming an electronic circuit that includes a plurality of circuit nodes externally accessible via the plurality of leads; subsequent to coupling the set of components to the first carrier, joining the first carrier to a second carrier to form a composite carrier; and assembling an immersive cooling assembly to at least partially enclose the composite carrier, the immersive cooling assembly being configured to guide a cooling fluid over the composite carrier.

Example 16: The method of any of the preceding examples, wherein: the immersive cooling assembly includes an inlet port configured to intake the cooling fluid and an outlet port configured to release the cooling fluid; and the immersive cooling assembly is configured to guide the cooling fluid over a first surface of the composite carrier and over a second surface of the composite carrier opposite the first surface.

Example 17: The method of any of the preceding examples, wherein the set of components includes an unpackaged semiconductor die implementing a singular power transistor.

Example 18: The method of any of the preceding examples, further comprising: forming, within the composite carrier, a plurality of vias configured to provide access to the plurality of leads; coupling a plurality of press-fit sockets to the plurality of vias to provide access to the plurality of vias; preparing an insert board with a plurality of press-fit pins configured to couple with the plurality of press-fit sockets; and coupling the insert board to the composite carrier by coupling the plurality of press-fit pins and the plurality of press-fit sockets, the insert board being external to the immersive cooling assembly when the insert board is coupled to the composite carrier.

Example 19: A power inverter assembly comprising: a first carrier and a second carrier, the first carrier being joined to the second carrier to form a composite carrier; a set of components forming a power inverter circuit, the set of components including a plurality of unpackaged semiconductor dies each implementing singular power transistors and the set of components being embedded within the composite carrier between the first carrier and the second carrier; a plurality of leads integrated with the composite carrier and configured to provide external access to a plurality of circuit nodes of the power inverter circuit; and an immersive cooling assembly configured for use in an automotive application, the immersive cooling assembly at least partially enclosing the composite carrier and configured to guide a cooling fluid over the composite carrier.

Example 20: The power inverter assembly of any of the preceding examples, wherein the immersive cooling assembly is configured to guide the cooling fluid over a first surface of the composite carrier and over a second surface of the composite carrier opposite the first surface.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An electronic assembly comprising:
a first carrier and a second carrier, the first carrier being joined to the second carrier to form a composite carrier;
a set of components forming an electronic circuit, the set of components being embedded within the composite carrier between the first carrier and the second carrier;
a plurality of leads integrated with the composite carrier and configured to provide external access to a plurality of circuit nodes of the electronic circuit; and
an immersive cooling assembly at least partially enclosing the composite carrier and configured to guide a cooling fluid over the composite carrier.

2. The electronic assembly of claim 1, wherein the immersive cooling assembly is configured to guide the cooling fluid over a first surface of the composite carrier and over a second surface of the composite carrier opposite the first surface.

3. The electronic assembly of claim 1, wherein:
the first carrier is a first printed circuit board (PCB);
the second carrier is a second PCB; and
the electronic circuit includes an electrical connection provided by the first PCB, the electrical connection including a first pad, a second pad, and a trace connecting the first pad and the second pad within the first PCB.

4. The electronic assembly of claim 1, wherein the immersive cooling assembly includes an inlet port configured to intake the cooling fluid and an outlet port configured to release the cooling fluid.

5. The electronic assembly of claim 1, wherein the set of components includes an unpackaged semiconductor die.

6. The electronic assembly of claim 5, wherein the unpackaged semiconductor die implements a singular power transistor.

7. The electronic assembly of claim 6, wherein the singular power transistor is a power metal-oxide-semiconductor field-effect transistor (MOSFET) fabricated using a silicon carbide (SiC) semiconductor.

8. The electronic assembly of claim 5, wherein the set of components further includes a conductive clip configured to electrically couple the unpackaged semiconductor die to another component within the electronic circuit.

9. The electronic assembly of claim 5, wherein the unpackaged semiconductor die implements an integrated circuit including a plurality of transistors.

10. The electronic assembly of claim 1, wherein the set of components includes a plurality of unpackaged semiconductor dies including a first semiconductor die fabricated using a silicon (Si) semiconductor and a second semiconductor die fabricated using a silicon carbide (SiC) semiconductor.

11. The electronic assembly of claim 1, wherein:
the composite carrier includes a plurality of vias configured to provide access to the plurality of leads; and
the electronic assembly further comprises a plurality of press-fit sockets configured to provide access to the plurality of vias.

12. The electronic assembly of claim 11, further comprising an insert board with a plurality of press-fit pins configured to couple with the plurality of press-fit sockets, wherein:
the insert board is configured to couple to the composite carrier by way of a coupling between the plurality of press-fit pins and the plurality of press-fit sockets; and
the insert board is configured to be external to the immersive cooling assembly when the insert board is coupled to the composite carrier.

13. The electronic assembly of claim 1, wherein the composite carrier includes a plurality of vias configured to provide access to the plurality of leads without press-fit sockets to provide access to the plurality of vias.

14. The electronic assembly of claim 1, wherein the electronic assembly implements a power inverter assembly configured for use in an automotive application.

15. A method comprising:
integrating a plurality of leads with a first carrier;
coupling a set of components to the first carrier, the set of components forming an electronic circuit that includes a plurality of circuit nodes externally accessible via the plurality of leads;
subsequent to coupling the set of components to the first carrier, joining the first carrier to a second carrier to form a composite carrier; and
assembling an immersive cooling assembly to at least partially enclose the composite carrier, the immersive cooling assembly being configured to guide a cooling fluid over the composite carrier.

16. The method of claim 15, wherein:
the immersive cooling assembly includes an inlet port configured to intake the cooling fluid and an outlet port configured to release the cooling fluid; and
the immersive cooling assembly is configured to guide the cooling fluid over a first surface of the composite carrier and over a second surface of the composite carrier opposite the first surface.

17. The method of claim 15, wherein the set of components includes an unpackaged semiconductor die implementing a singular power transistor.

18. The method of claim 15, further comprising:
forming, within the composite carrier, a plurality of vias configured to provide access to the plurality of leads;
coupling a plurality of press-fit sockets to the plurality of vias to provide access to the plurality of vias;
preparing an insert board with a plurality of press-fit pins configured to couple with the plurality of press-fit sockets; and
coupling the insert board to the composite carrier by coupling the plurality of press-fit pins and the plurality of press-fit sockets, the insert board being external to the immersive cooling assembly when the insert board is coupled to the composite carrier.

19. A power inverter assembly comprising:
a first carrier and a second carrier, the first carrier being joined to the second carrier to form a composite carrier;
a set of components forming a power inverter circuit, the set of components including a plurality of unpackaged semiconductor dies each implementing singular power transistors and the set of components being embedded within the composite carrier between the first carrier and the second carrier;
a plurality of leads integrated with the composite carrier and configured to provide external access to a plurality of circuit nodes of the power inverter circuit; and
an immersive cooling assembly configured for use in an automotive application, the immersive cooling assembly at least partially enclosing the composite carrier and configured to guide a cooling fluid over the composite carrier.

20. The power inverter assembly of claim 19, wherein the immersive cooling assembly is configured to guide the cooling fluid over a first surface of the composite carrier and over a second surface of the composite carrier opposite the first surface.
